(19) United States
(12) Patent Application Publication
(10) Pub. No.: US 2009/0242021 A1
(43) Pub. Date: Oct. 1, 2009

(54) SOLAR CELL WITH COLORIZATION LAYER

(75) Inventors: Ronald Petkie, Thousand Oaks, CA (US); Rhonda Dibachi, Albuquerque, NM (US); Bruce Leising, Albuqueruqe, NM (US); Farzad Dibachi, Albuquerque, NM (US)

Correspondence Address: SCHWEGMAN, LUNDBERG & WOESSNER, P.A., P.O. BOX 2938, MINNEAPOLIS, MN, 55402, US

(73) Assignee: Noribachi LLC, albuquerque, NM (US)

(21) Appl. No.: 12/060,012

(22) Filed: Mar. 31, 2008

(51) Int. Cl. H01L 31/00

(52) U.S. Cl. 136/256

(57) ABSTRACT

Colorization of a solar cell is achieved by modifying a layer proximate an active layer of the solar cell. The color attribute may be obtained by selecting one or more narrow bands of wavelengths in the visible color spectrum to be reflected from the surface of the solar cell unit that results in a specific color or combination of colors at various angles. The spectrum of light reflected from the active solar cell area is controlled through the use of filters that reflect only limited portions of the spectrum, thereby minimizing the effect of reflected light on the overall efficiency of the solar cell.

### BACKGROUND

The solar cell industry has seen a burgeoning growth in recent years. This growth is due to increased cell efficiency and decreased manufacturing costs, driving the cost per watt to attractive levels in power generation and consumer markets. The initial impetus and competition for the solar cell manufacturers has been focused on the cost per watt through improvements for mostly grid-tied applications.

Consumer applications that incorporate solar cell units have also grown significantly because of lower costs. Consumer applications typically involve isolated electrical systems for lower power generation for charging batteries, where the consumer is generally in close proximity to the product.

One of the methods used in increasing the conversion efficiency of solar cell units is to optimize the solar cell's absorption of the solar light, based on the average available solar spectrum in the atmosphere. Anti-reflection coatings on the solar cell material itself, as well as packaging materials such as module glass, have been the topic of much research in the solar cell industry. Additional efforts involve texturing the surface of the solar cell material such that reflection is also reduced and the solar cell material appears almost black, which implies near maximum absorption of light. Hence, it is considered in the solar cell industry that a black solar cell is an ideal one from the standpoint of maximum energy conversion. Most commercial research efforts have focused on maximizing the transmission of available light into the solar cell material for conversion into electrical energy, and many solar cells on the market essentially appear black.

### BRIEF DESCRIPTION OF THE DRAWINGS

FIG. 1 is a block diagram of a solar cell having a layer with desired color properties according to an example embodiment.

FIG. 2 is an illustration of the spatial variation of the index of refraction in a rugate film from top to bottom disposed over a solar cell according to an example embodiment.

FIG. 3 is an outline of a set of equations for rejection of a given wavelength of light in a rugate film.

FIG. 4 illustrates relationships between reflected light and parallel planes that represent the variation of the index of refraction in rugated filters.

FIG. 5 is a graph of an example multiple notch rugate filter that rejects two infrared wavelengths, 827 nm and 1055 nm, and a visible wavelength at 634 nm.

FIG. 6A is a block diagram illustrating a test device for measuring how a laser of a specific wavelength can be reflected by a rugate filter at a specific angle according to an example embodiment.

FIG. 6B is a graph illustrating measured transmission of light at different wavelengths utilizing the test device of FIG. 6A.

FIG. 7 is a graph illustrating transmission of light for a dichromated gelatin rugate filter that rejects multiple bands in the visible spectrum according to an example embodiment.

FIG. 8 is a block diagram of a rugated filter in conjunction with solar cell unit illustrating different colors viewed by observers at different angles according to an example embodiment.

FIGS. 9A and 9B illustrate respective current-voltage and power-voltage curves for a silicon solar cell unit when illuminated with and without a rugate filter covering an active area of the solar cell unit according to an example embodiment.

FIG. 10 is a block schematic illustration of a mid-section of interleaved flexible solar cell strip units to form a flexible woven mesh module according to an example embodiment.

FIG. 11 is a block schematic illustration of a bi-directional solar cell mesh in a net design with a fixed border according to an example embodiment.

FIG. 12 is a block schematic illustration of a string of woven mesh modules combined in series to form a panel according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

Commercial research efforts have mostly focused on maximizing the transmission of available light into the solar cell material for conversion into electrical energy, and the ideal solar cell appears black. The value of grid-tied solar cell units is not only based upon their capability to generate power, but also upon their overall visual appearance, which is especially important in rooftop residential design.

Consumer applications typically involve isolated electrical systems for lower power generation for charging batteries for lighting or other products, where the consumer is generally in close proximity to the product. Consumers may be sensitive in terms of the overall visual appeal of the solar cell units, yet also desire solar cells that are efficient in providing power. For aesthetic design purposes, it is desirable that the solar cell units follow a product form factor to have appeal while adding unique value in providing power. The solar cell is thus integrated with the product.

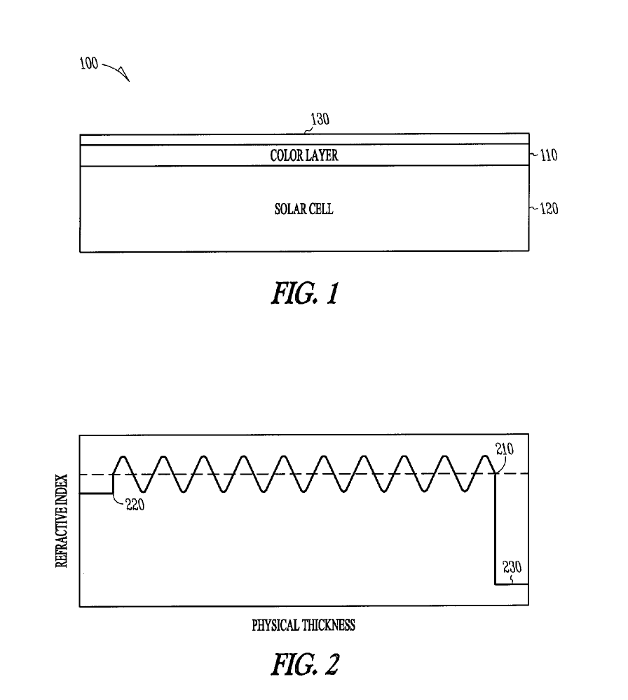

Various embodiments are described that involve the addition of a color component or layer 110 to an active area 120 of a solar cell unit 100 as illustrated in block diagram form in FIG. 1. The color component may be used to obtain desired colors of the solar cell unit without significantly reducing the conversion efficiency by a large degree. The use of one or more layers on a solar cell unit provides tools for product designers to include aesthetic considerations into their product design efforts.

Colorization of a solar cell unit may be done in various embodiments through the use of a rugate filter layer 110, also referred to as a band stop, notch, holographic mirror, or reflective Bragg filter (or optical element). Such filters will be generally referred to as Rugate filters in the following description. In further embodiments, other types of color modifying techniques may be used in various layers of the solar cell unit, such as by modifying reflective properties of anti-reflective coatings or layers normally utilized to prevent reflection of incident light. Such layers include but are not limited to silicon nitride, silicon dioxide, silicon carbide, mixed stoichiometric films (Si_{w}OₓN_{y}C_{z}), or other thin films or combinations thereof. Such thin films and combinations may also be used to create an interference pattern to create colorizing effects. In still further embodiments, gelatinous filters may be applied to the surface of a solar cell unit to provide a color in conjunction with the overall optical properties of the solar cell unit.

A Rugate filter 110 reflects a specific portion of wavelengths in the electromagnetic spectrum for which it is designed, and at a specific angle of diffraction and a given angle of incidence with respect to the surface of the filter. Light at other wavelengths is transmitted through the filter at that angle of incidence. A rugated filter consists of a film where the index of refraction varies throughout the thickness of the film such as to reflect specific wavelengths of light.

When such a filter 110 is placed on the surface of an illuminated solar cell unit, the solar cell unit acquires a color at a specific angle. Since solar cells are normally intended to absorb as much light as possible through anti-reflective coatings, most of the light will be transmitted through the filter and be used to generate power in the solar cell unit in accordance with the original functionality. Since only a small narrow band of the light spectrum is reflected back to an observer, the solar cell unit has effectively been ‘colorized’ in the visible region of the spectrum.

Various embodiments provide a means to preserve most of the potential power generation aspects of the solar cell. Embodiments may also provide an aesthetic appeal to the solar cell unit and even provide further functionality in terms of rejecting infrared wavelengths that would otherwise cause the cell to operate at higher temperatures.

Rugate filters may be referred to as colorization filters. Such colorizing filters may be fabricated by one or more of the following methods. A first method is referred to as a recording hologram, also known as a volume phase hologram (VPH), which contains parallel planes of a periodically varying index of refraction through its thickness at a chosen angle of orientation with respect to the filter's surface. The recording hologram layer can be made by directly depositing one or more recording materials by spin, spraying, or bar coating apparatus onto a substrate, such as a solar cell or the module glass covering the solar cell active area.

Rugate filter design and method of fabrication depends on whether the mode of exposure for the photosensitive materials is based upon reflection (silicon substrate with anti-reflective coating) or transmission (module glass). Holographic filters can be manufactured by exposing the photosensitive film with two lasers in order to create an interference pattern consistent with the spatial variation required in the index of refraction within the film in accordance to the filter design, namely the center wavelength selected for rejection. Additional consideration of the phase changes in the laser beam, which is dependent on the sequence of particular materials in use during exposure, is necessary when a reflective mode is used.

Photosensitive materials, often made by dissolving a solid material into a liquid solvent, can include a variety of materials, such as dichromated gelatin (DCG), polyvinyl carbazole (PVK), and DMP128 (a Dupont material), and Omnidex 352 (a Polaroid material) and typically range in thickness from about 5 microns to 25 microns. The maximum change in the index of refraction and its sensitivity (slope) with laser intensity (energy/area) is different for each photosensitive material. Each of these photosensitive materials can be chosen in accordance with the Rugate filter design requirements and stability. DCG is one of the most flexible materials in terms of sensitivity and maximum change in the index of refraction.

The Rugate filter design may include one or more laser wavelengths, each of which may have an arbitrarily chosen exposure angle of incidence between the laser exposure beam and the surface of the photosensitive film plane. The deposited photosensitive film is then exposed to one or more lasers of chosen wavelengths and at one or more specific angles in a manner consistent with the overall Rugate filter design and the photosensitivity of the film. The filter layer may be developed (if necessary for the recording material) to create a modulated index of refraction for the Rugate filter.

In a further embodiment, referred to as a transferable hologram film, the process described above is repeated on a transferable film hologram substrate. The resulting Rugate film 110 is overlaid or attached onto the illuminated surface of the solar cell unit 120. A series of such films may be overlaid to create an overall colorization effect.

In a further embodiment, referred to as a dielectric film, a solar cell unit or protective module glass is placed in a vacuum system, such as in a plasma-enhanced chemical vapor deposition chamber, designed to continuously deposit (for example) films with continually varying indices of refraction. As an example, a film consisting of sequential layers of dielectric films ranging from silicon dioxide (SiO₂) to silicon nitride, (Si₃N₄), and the silicon oxynitrides (SiₓO_{y}N_{z}) with indices of refraction between that of silicon dioxide and silicon nitride, is a method for easily fabricating a dielectric film Rugate filter on a solar cell unit or module glass. This method provides the ease of manufacturability, which is accomplished by incrementally varying the index of refraction during deposition by changing the gas flow ratio of nitrous oxide to ammonia in order to correspondingly change from a silicon dioxide film to a silicon nitride film. A film of any desired index of refraction, between that of silicon dioxide and silicon nitride, can then be deposited in accordance with a Rugate design, which involves a periodic variation in the index of refraction.

The optional layer 130 can thus be deposited with the level of complexity consistent with the requirements in the index of refraction and thicknesses as required by Rugate filter design. Layer 130 serves to match the index of refraction of the Rugate filter with the air to reduce further reflection.

In addition, this method of deposition is flexible, and can include the process for a “standard” notch filter, where only two indices of refraction are selected (such as silicon dioxide and silicon nitride films) rather than a continual range of indices (silicon oxynitride films), which is an option in the filter design. Optionally, apodization matching of the index of refraction with the interface materials on the bottom and top of the film can be done for maximizing transmission of the power generating portion of the electromagnetic spectrum through the surface of the solar cell unit, such as layer 130.

In a further embodiment, a transferable dielectric film may be formed as above with the dielectric film. It may be formed on a glass or plastic covering for the solar cell units, which may be a permanent or non-permanent part of the solar cell units.

In still further embodiments layers other than a Rugate filter may include the de-optimization of an anti-reflection coating(s) on a solar cell unit. For example, silicon nitride or silicon dioxide, or any other thin film or combination thereof, that results in an overall interference pattern in accordance with Bragg's law of interference in thin films, may be used to create a colorizing effect. Thus, layer 110 may also be a modified anti-reflection coating that provides a desired color appearance for the solar cell unit 120.

Modifying the properties of an anti-reflection coating is least expensive since it only involves modifying the deposition process currently used in most silicon solar cell manufacturing processes. While perhaps not providing the broadest color palette, the process may be applied to flexible substrates by using PE-CVD reactors, such as for making the rugate filters on plastics at less than 100 degrees Celsius.

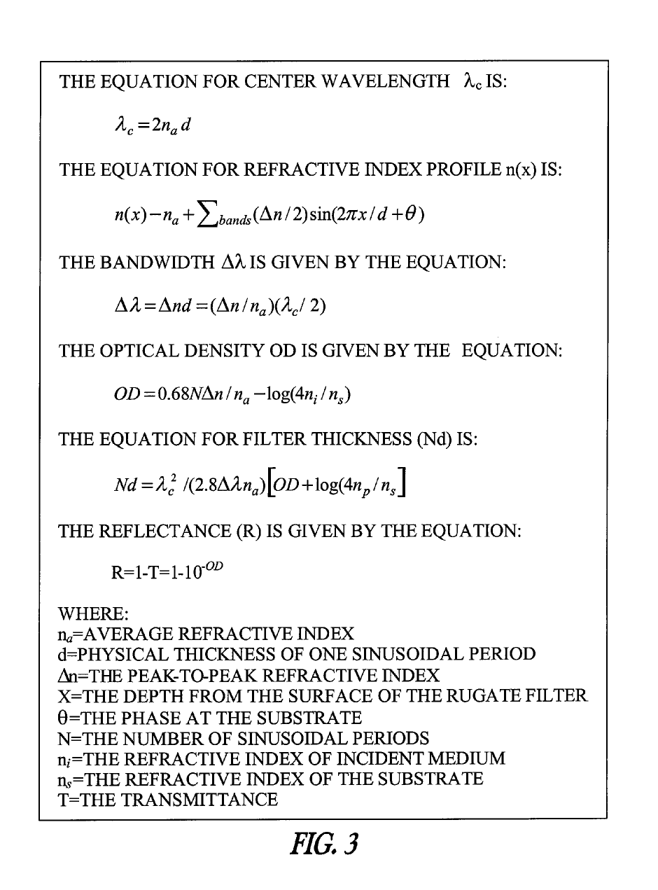

FIG. 2 is an illustration of the spatial variation of the index of refraction in a rugate film from top 210 to bottom 220 disposed over a solar cell indicated at 220 and the air interface at 230 according to an example embodiment. In one embodiment, the rugate film is a dielectric layer or hologram made from dichromated gelatin. The thickness of the film and the variation of the index of refraction within the film controls the center wavelength of light rejected, the bandwidth on both sides of the center wavelength, and the optical density of the filter. Multiple variations added together result in a periodic but non-sinusoidal variation in the index of refraction and multiple rejection bands to create any combination of colors.

FIG. 3 is an outline of a set of equations for rejection of a given center wavelength of light in a rugate film. Several rejection bands at different center wavelengths may be combined to create multiple rejection rugate filters to form unique colors. The index of refraction is modified Δn at a specific layer within the film, which is chosen in accordance with limitations of the deposition process. The optical density, OD, is chosen to accommodate the desired amount of reflection, given by R, of the center wavelength, and determines the required thickness of the film, the product of Nd, for a desired intensity of reflection. Obviously, for a chosen incident index of refraction in the film, nᵢ (preferably low), a given substrate of nₛ (glass or silicon), a selected OD (to obtain a reasonable amount of reflection, such as 50%), nₐ (process and material dependent), if the value of Δn is chosen to be large, then a lower the value of N is required, which reduces the required thickness of the film.

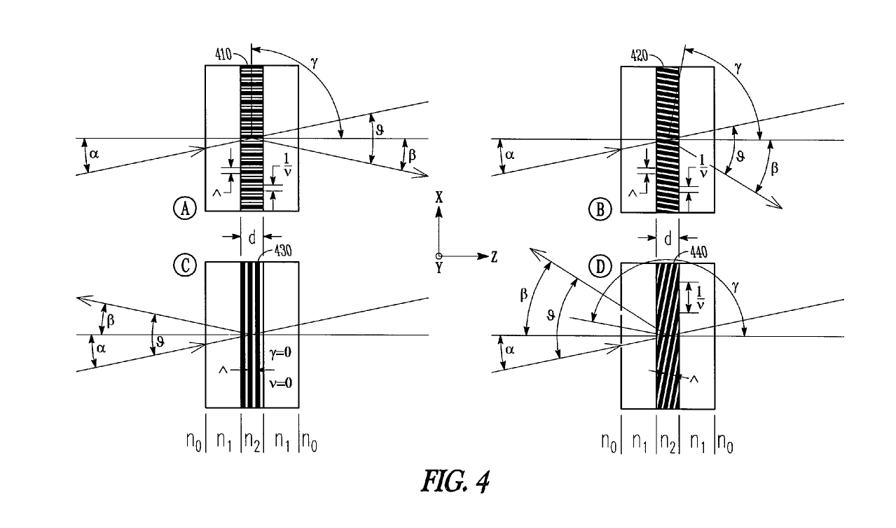

FIG. 4 illustrates relationships between reflected light and parallel planes that represent the variation of the index of refraction in rugated filters. The angle of incidence of light does not need to be normal to parallel planes of the index of refraction for rejection of a wavelength to occur. The rejected wavelength and the angle at which rejection occurs is determined by the Bragg condition of constructive interference and the harmonics for that wavelength. By tilting the plane in which the index of refraction occurs with respect to the substrate surface on which the rugate filter is made, the wavelength and angle of reflected light can be arbitrarily controlled.

FIG. 4 at A represents normal reflected light and a transmission grating with fringes 410 perpendicular to the grating surface. In this case, the incident angle of light, α, and diffracted light angle, β, are also the Bragg angles.

In FIG. 4 at B, a transmission grating with tilted fringes 420 is shown, with an incident light at the angle, α, but with the diffracted light corresponding to angle, β, different than the incident angle of light, both with respect to the filter's surface. In this case, the Bragg angle is given by 90−γ and the diffracted light occurs at an angle different than the incident light with to respect to the filter's surface.

FIG. 4 at C illustrates a reflection grating with fringes 430 parallel to the grating surface. This grating does not disperse the light, and would typically be used to reflect light normal to the surface of the filter. Here, the Bragg angle is 90−α, and the angle of incidence again equals the angle of diffraction.

FIG. 4 at D illustrates a grating with an alternate tilting of fringes 440, which are closer in angle to fringes 430. Fringes 440 provide a modulated index of refraction made at an angle with respect to the optical element's surface in order to reflect light coming in at near normal incidence away at a predetermined angle from normal incidence. This particular orientation is suitable for an application involving the colorization solar cells. Ordinarily, the incident light should be normal to the surface of the solar cell, and colorization can be attained by making the normal of the plane of interference fringes at an angle 180−γ with respect to the solar cells surface. Once again, the angle of incidence, α, which is preferably 0 degrees for maximum light absorption at wavelengths other than the notch wavelength, is different than the angle, β, at which the diffracted color appears to the observer. Thus, maximum energy is absorbed and the solar cells appear aesthetically pleasing at the same time. This particular method is suitable for rooftop colorized solar cells for a residence or commercial building.

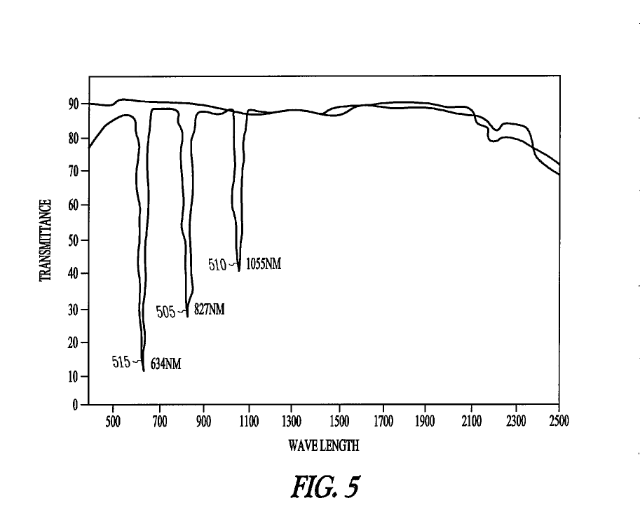

FIG. 5 is a graph of an example multiple notch rugate filter that rejects two infrared wavelengths, 827 nm at 505 and 1055 nm at 510, and a visible wavelength at 634 nm at 515. This rugate filter would appear red in sunlight to an observer if (1) looking in a line of sight perpendicular to the surface of the filter, and (2) the plane of index variation and the plane of rugate filter surface are parallel, and (3) the angle of incident light is normal to the filter surface. Utilizing both the ability to select one or more frequencies that can be reflected, along with the ability to angle the fringe, allows a designer to select different color appearances for likely views of a product incorporating such colorized solar cells. For instance, if roofing material were to incorporate or have solar cell units coupled to them, the angle of a viewer on the ground may be incorporated into the aesthetic design, such that viewer on the ground would see a desired color. The same design color theory may be used for many different products incorporating solar cell units.

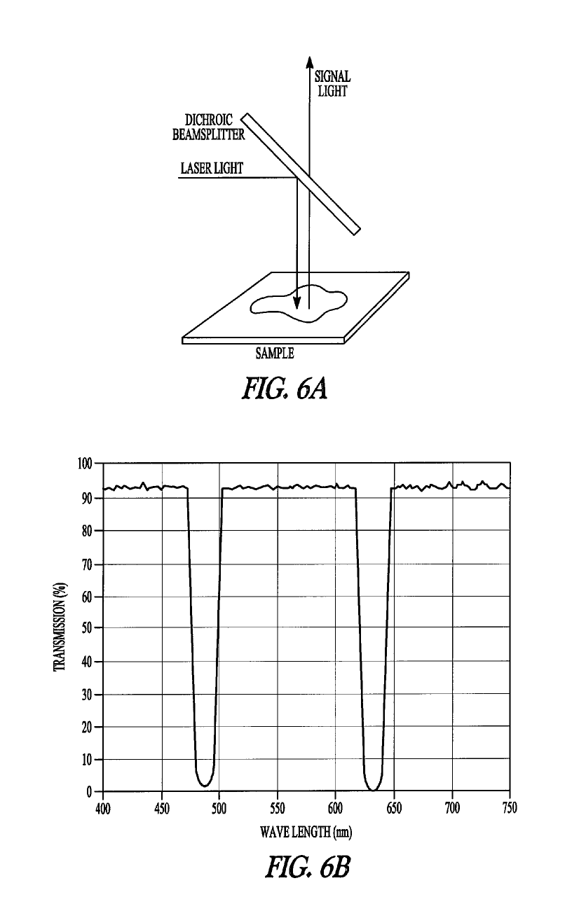

FIG. 6A is a block diagram illustrating a test device for measuring how a laser of a specific wavelength can be reflected by a rugate filter at a specific angle according to an example embodiment. FIG. 6B is a graph illustrating measured transmission of light at different wavelengths utilizing the test device of FIG. 6A. The figures reveal how a laser of a specific wavelength can be reflected by a rugate filter at a specific angle by considering the laser wavelength, angle of incidence of the laser light, and orientation of the plane of index variation with respect to the rugate filter surface. This application of a rugate filter rejects light of the laser wavelength but transmits light of other wavelengths in the given geometric configuration for observation of the sample.

FIG. 7 is a graph illustrating transmission of light for a dichromated gelatin rugate filter that rejects multiple bands in the visible spectrum according to an example embodiment. Different center wavelengths, 450 nm at 705, 550 nm at 710, and 650 nm at 715 are illustrated. The combination of these reflected bands, with their center wavelengths and intensities, are used to create a specific color when viewing the filter at various angles, thus making a color holographic filter. A dashed line illustrates the result obtained with a theoretical simulation.

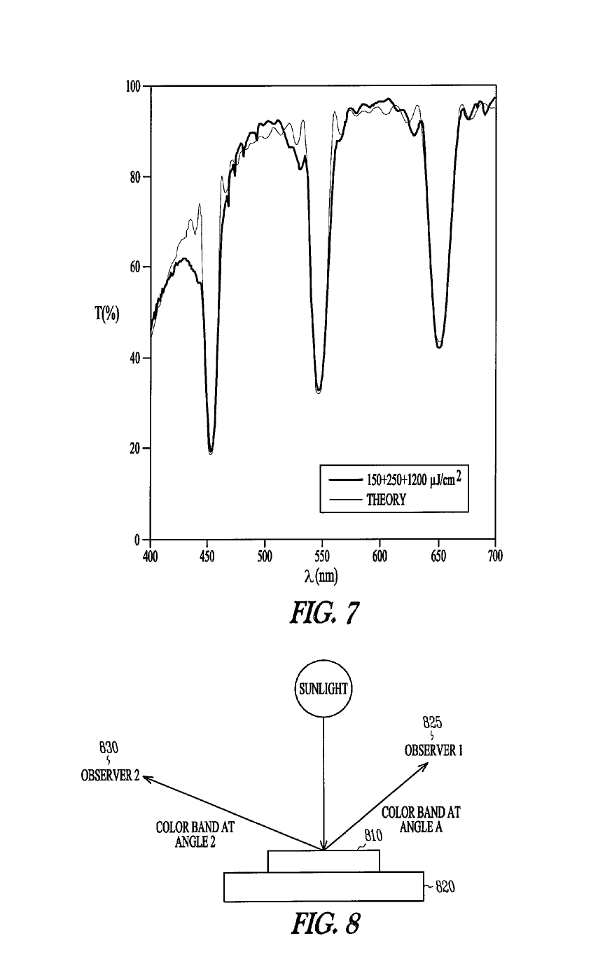

FIG. 8 is a block diagram of a rugated filter in conjunction with solar cell unit illustrating different colors viewed by observers at different angles according to an example embodiment. A rugated filter 810 may be used as a layer over a solar cell unit 820. In one embodiment, filter 810 has two combined sets of index variations oriented at different angles. Observer 1 at 825 and observer 2 at 830 see different colors or the same color depending on rugate filter design and geometric design.

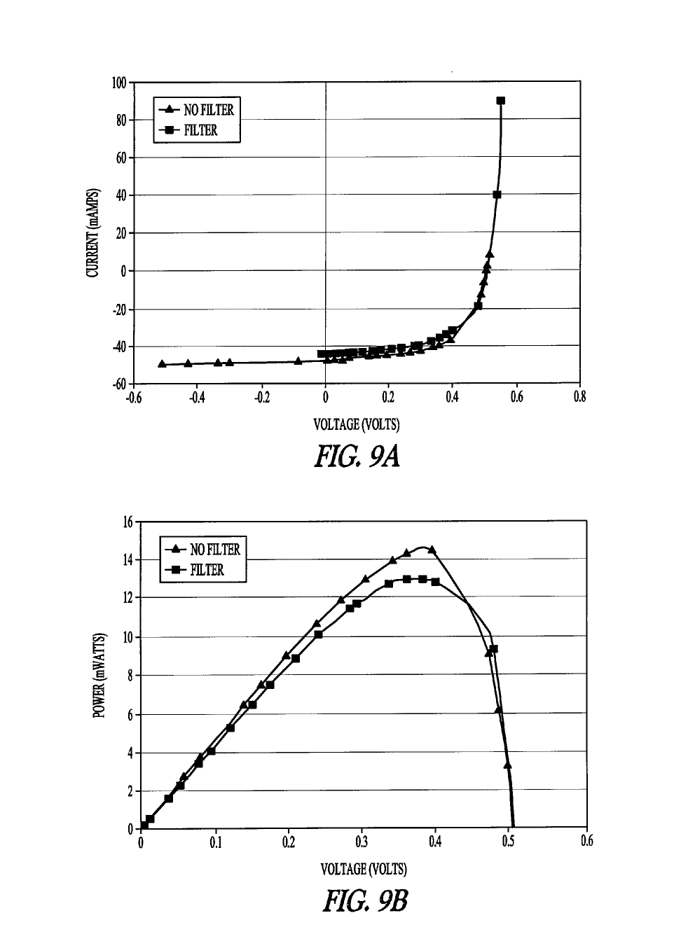

FIGS. 9A and 9B illustrate respective current-voltage and power-voltage curves for a silicon solar cell unit when illuminated with and without a rugate filter covering an active area of the solar cell unit according to an example embodiment. In one embodiment, illumination is provided an indoor halogen lamp and the active area of the solar cell unit is approximately 1 inch². The power output is shown to drop by slightly less than 10% with the rugate filter.

In a further embodiment a rugate filter design uses a dichromated gelatin for colorizing a solar cell unit with the color red, when viewed at an angle of 45 degrees, and the color green, when viewed form 30 degrees, from the surface of the filter. A laser may be used to expose a dichromated gelatin (DCG) film with a single or combined lasers of different frequencies such that the DCG is exposed to create both a infrared reflection filter and a reflector for a visible color to impart a color to the solar cell. In addition, a colored gelatinous filter may be placed on the surface of the solar cell unit to provide a color to its surface. The inherent color of the solar cell units can be combined with the gelatinous filter to create the final color by considering the combined reflected colors from both surfaces, the surface of the solar cell unit and the gelatinous filter.

In one embodiment, a mesh including strips of solar cell unit material having a layer with tailored color properties may be conformed to fit a curved surface. The strips of solar material may be cut from a specifically designed modular type array of solar cells formed on a flexible backing, such as Mylar or thin metal foil such as aluminum. The strips of solar material may then be weaved or tied with other flexible strips to form a mesh. The mesh may take the form of a fabric or net. The mesh may be applied to a curved surface in a conformal manner, thus allowing a product to be designed independently of the exact location of the light source, with the mesh then being applied to the finished design of the product. In some embodiments, the mesh may have solar strips and other non-solar strips woven in a manner to form a pleasing design as opposed to optimized for solar conversion efficiency. Color may also be introduced into the mesh independent of the solar strip manufacturing chemistry to add further aesthetic design capability.

Products incorporating solar materials have not generally been designed from an aesthetic point of view. Some embodiments of the present invention allow such design at least because of the ability to design aesthetically pleasing meshes from both color and texture perspectives, and the ability to conform them to a large variety of surfaces.

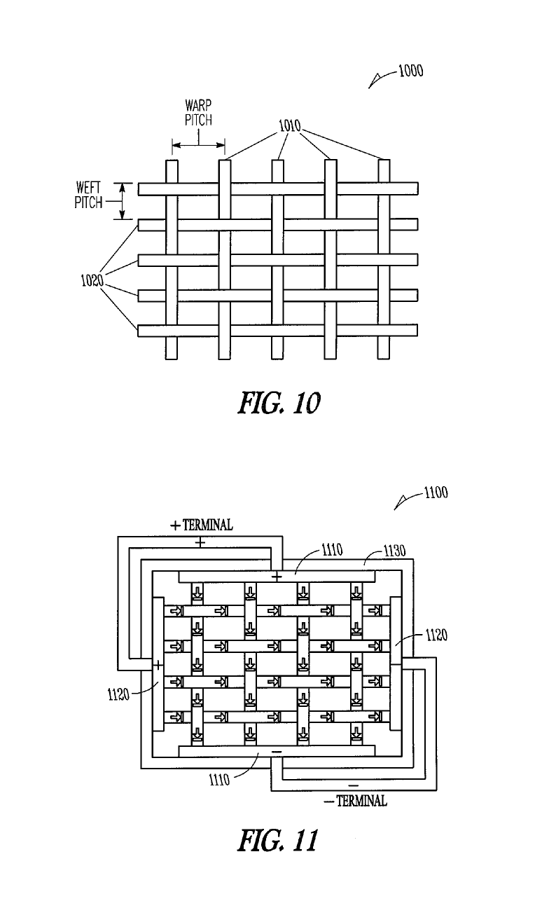

FIG. 10 is a top view of a block diagram representation of a section of a flexible solar cell woven mesh as an example embodiment. In one embodiment, first strips of solar cell unit material 1010 are oriented in a first direction. Second strips 1020 of either further solar material or other material may be woven or tied into the first strips 1010. The first strips 1010 and second strips 1020 are at least partially orthogonal to each other, and in one embodiment are substantially perpendicular to each other. In still further embodiments, different types of weaves may be used where the angle between the sets of strips is varied significantly, and in still further embodiments, more than two sets of strips may be woven together.

In one embodiment, either material may be a warp or weft according to classic weaving terms. In one embodiment, second strips 1020 may be formed of a stronger or more durable material, and may be used as a warp in a manufacturing process, with the first strips of solar cell material woven into them to form a fabric or net. In one embodiment, the second set of strips 1020 may be at least partially transparent to maximize light collection by the set of solar cell strips. Pigments may be included in the strips, or in an epoxy like encapsulation of the mesh when applied to a desired surface to further increase aesthetic design flexibility and protect the solar material from ultraviolet radiation.

The warp pitch and weft pitch is given by the width of the warp and weft strips plus the spacing between the strips, respectively. That is,

Pitch of Warp=Warp strip width+Warp spacing

Pitch of Weft=Weft strip width+Weft spacing

An example of a closed mesh, which defines a fabric article, is the case where either the warp or weft spacing is about 0 mm. Cases when both pitches are greater than 0 mm results in a net weave. The mechanical properties of the mesh, namely the flexibility and conformability, and the electrical output of the solar cell strips, namely the total power generation, are inter-related through the physical and electrical attributes of the warp and weft. For example, the pitch of the warp and weft directly influence mechanical properties, namely flexibility, while the detailed nature of solar cell units in the strip design directly influence the collective voltage and currents of the mesh, namely power generation, just as in solar cell module design.

It is assumed that the intensity of light available on the surfaces of solar cell strips within the mesh will, in general, be non-uniform, as the mesh as whole may be used outdoor on curved surfaces. Non-uniform illumination in an array of solar cell units causes ‘shading effects’, which can lead to array failure when operating at high current levels. The flexible mesh described here may have an array operating at lower current levels such that the mesh or array does not suffer from the same shading heating effects as in conventional solar cell modules.

Similarly, individual solar cell units in a flexible strip may be in series and typically possess low shunt resistance and high reverse current character. These electrical properties imply that if a particular solar cell unit in a strip is completely shaded by a strip above it, the photo-generated current from other illuminated units may still pass through the shaded unit. Hence, solar cell strips with periodic dark or shaded area, as determined by the pitch in the opposite weave, will not have the effect of eliminating photo-generated current in a strip.

In one embodiment, the first strips of solar material 1010 may be cut from a solar panel. The solar panel may be formed using thin film processes to produce solar cells on a flexible substrate, such as Mylar or metal foil. The resulting commercially available panels are somewhat flexible, as the solar cells may have a thickness of about 1 mm. The additional substrate may also be flexible. The strips may be cut using a knife, laser, or any other method desirable.

Optimization of mechanical and electrical performance of a mesh of strips collectively may be obtained by selecting the dimensions and solar cell diode layout within the solar cell panel consistent with the strips to be obtained from the panel. The strips may be cut and woven to form a mesh optimized for a specific product. When the strips are woven together to form a net or fabric, the resulting net or fabric may be more flexible than the original solar panel. Thinner strips may be used to further increase the flexibility of the resulting mesh. Different weaves may also be utilized to allow for a more flexible and hence conformable mesh, such as a fabric or net.

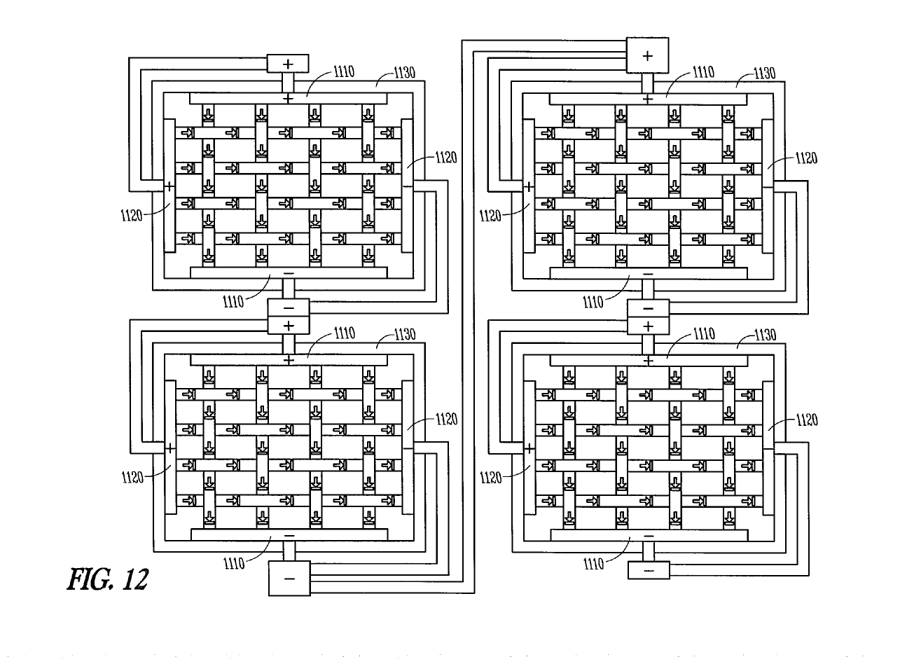

In one embodiment, the strips may be tied or otherwise coupled at selected locations to form a mesh 1100 in the form of a net as illustrated in FIG. 11.

As a very basic example embodiment, the mesh 1100 in FIG. 11 includes woven solar cell strips in a bi-directional design with a substantially matched number of solar cell diodes in each strip. These strips can be cut from commercially available Mylar substrate solar cell diode arrays. Each strip consists of diodes connected in series as shown to essentially match the pitch of the warp and weft in this case of a net weave. All strips are designed to have substantially the same operational performance as determined by the solar cell manufacturing process and to minimize performance mismatching effects in the collection of photo-generated power. In one embodiment, the strips may be connected in parallel for each set of strips within the warp and weft. Terminals may be electrically coupled to provide an electrical output suitable for a designed product.

As a specific example of a fabric design in FIG. 11, where the spacing is approximately 0 mm and again made from available flexible solar cell panels, the overall designed could be about 4.5 by 2.0 inches for a rectangular shaped design. Four strips having similar electrical characteristics in each direction, with each strip width of 0.5 inches wide by 4.5 inches long, with an allowance of 0.5 inches in the length for the conductive strip terminals. Each strip in one embodiment has 5 solar cell diodes in series. Typical maximum power operating voltages in AM1.5 illumination for a single diode is about 0.6 volts, so the output voltage for a strip of 5 solar cell diodes in series is 3.0 volts. The operating current for the same condition is typically 0.011 amps for each strip, which yields an output power of 0.033 watts for each strip in the fabric. Since there are a substantially equal number of diodes in series in each strip, under ideal conditions, the output voltage will be the same for each strip, and be equal for each set of warp and weft strips. The warp and weft strips can be connected in parallel to provide the final output power.

In a further embodiment, each strip is capable of generating 0.011 amps under normal operating conditions, and there are 8 strips in all, resulting in a potential operating output current could of 0.088 amps at 3.0 volts. Thus, the potential power is 0.26 watts without consideration of shadowing effects from the interleaved strips. In still further embodiments, mesh 1100 may be considered an example of a basic mesh module, where modules may be combined for additional power output.

The operational power output of a mesh, with interleaved shading effects, is estimated by considering the area shaded. For one example embodiment, where there are an equal number of strips (4) in each the warp and weft and all strips have approximately the same width. The total shaded area for either the warp of weft in the design is given by 8×0.5″×0.5″=2 in². The total active area of the solar cell strips is given by is given by 4″×2″=8 in². Assuming the maximum available power is roughly given by the illuminated area, and the illuminated area is reduced by 25% from interleaved shading effects, then the operational power level is estimated to be 75% of the normal operational power level. The power output for this design with the shading effect is then about 0.19 watts.

FIG. 12 illustrates the cumulative effects of adding the basic module design mesh 1100 in FIG. 11, analogous to panel design in the larger solar cell module and panel arrays. The interleaved mesh 1100 of FIG. 11 defines a module and can be used to make a solar cell panel capable of providing 12 volts as output for re-charging batteries. More specifically, by stringing four mesh 1100 module units in series to increase the voltage to 12 volts, the available power is four times that of the unit design, which is estimated to be 0.78 watts with shading effects considered. Similarly, the maximum available current may be increased by adding another 1×4 module in parallel, increasing the maximum power achievable by an additional 0.78 watts per added module. In addition, the width of the strips may be selected to provide a desired amount of current flow for each strip. Sets of strips having desired voltages and current may be coupled in series or in parallel to provide desired voltage and current characteristics. Insulation from the original solar panel used to form the strips may be removed at desired positions, such as ends of strips, and electrical connections made at such positions.

Typical lengths for the strips of solar materials range from 15 cm to 90 cm. Lengths of at least up to 45 m or longer may be used in further embodiments. In some embodiments, a strip may contain several cells that are coupled in series to provide a desired voltage. The width of a strip is proportional to the amount of current that can be provided. The width of the strip may be a trade off between several factors, including aesthetic factors, conformal factors, and current factors. Typical widths of the solar strips range from less than 0.5 cm to about 3 cm. Wider widths may be used if desired, such as for use in covering very large surfaces, which may be viewed from a distance. Aesthetic design desires may lead to the use of a larger width for viewing at a distance in accordance with aesthetic design desires.

A further embodiment involves the electrical properties of the solar cells themselves. Normally, a by-pass diode is required in modules to accommodate shading effects and prevent overheating and possible destruction. Such a by-pass diode routes current around the shaded solar cell. Additionally, to maximize the efficiency in solar cells, the cells are typically designed to have a high shunt resistance. In thin film flexible solar cells used in applications where shading may occur during a significant portion of the operational lifetime, a lower shunt resistance is advantageous. A solar cell with relatively low shunt resistance will allow current to pass through it even when 100% shaded, as it then operates as a series resistor, rather than preventing photo-generated current from flowing altogether, which could be the case for an ideal solar cell diode.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

1. A device comprising:
a solar cell; and
a colorization layer coupled to the solar cell that trades off reflectance minimization with colorization.

2. The device of claim 1 wherein the colored layer comprises a filter that reflects one or more wavelengths of light.

3. The device of claim 2 wherein the filter comprises a rugate filter.

4. The device of claim 3 wherein the filter comprises sequential layers of dielectric films having different indices of refraction.

5. The device of claim 4 wherein the sequential layers are apodization matched.

6. The device of claim 1 wherein the colorization layer comprises a hologram film.

7. The device of claim 1 wherein the colorization layer comprises a transferable dielectric film.

8. The device of claim 1 wherein the colorization layer comprises a colored gelatinous filter.

9. The device of claim 1 wherein the colorization layer comprises an anti-reflective film modified to reflect one or more desired wavelengths at the expense of solar cell conversion efficiency.

10. The device of claim 9 wherein an interference pattern is created in the anti-reflective film.

11. The device of claim 1 wherein the addition of a colorization layer increases reflectance of the solar cell by at least approximately 10 percent.

12. A device comprising:
a solar cell;
an anti-reflectance layer optimized to minimize reflection of light away from the solar cell; and
a colorization layer formed over the anti-reflectance layer to provide colorization of the device.

13. The device of claim 12 wherein the colored layer comprises a filter that reflects one or more wavelengths of light.

14. The device of claim 13 wherein the filter comprises a rugate filter.

15. The device of claim 14 wherein the filter comprises sequential layers of dielectric films having different indices of refraction.

16. The device of claim 15 wherein the sequential layers are apodization matched.

17. The device of claim 12 wherein the colorization layer comprises a hologram film.

18. The device of claim 12 wherein the colorization layer comprises a transferable dielectric film.

19. The device of claim 12 wherein the colorization layer comprises a colored gelatinous filter.

20. The device of claim 12 wherein the solar cell comprises a mesh formed of strips of flexible solar material wherein the strips are electrically coupled to each other.

21. A method comprising:
forming a solar cell; and
forming a colorization layer coupled to the solar cell that trades off reflectance minimization with colorization.

22. The method of claim 21 and further comprising integrating the solar cell with colorization layer with a product.
